(19) United States
(12) Patent Application Publication
(10) Pub. No.: US 2026/0244026 A1
(43) Pub. Date: Aug. 20, 2026

(54) BEAM PATTERN SHAPING WITH BI-CONVEX MICRO-LENS

(71) Applicant: Lumileds Singapore Pte. Ltd., Singapore (SG)

(72) Inventors: Florent MONESTIER, Aachen (DE); Toni LOPEZ, Aachen (DE)

(73) Assignee: Lumileds Singapore Pte. Ltd., Singapore (SG)

(21) Appl. No.: 19/539,941

(22) Filed: Feb. 13, 2026

Related U.S. Application Data
(60) Provisional application No. 63/758,780, filed on Feb. 14, 2025.

(51) Int. Cl. G02B 27/09; G02B 9/34; G02B 9/60; G02B 9/62; G02B 9/64

(52) U.S. Cl. CPC G02B 27/0927; G02B 9/34; G02B 9/60; G02B 9/62; G02B 9/64

(57) ABSTRACT

LED devices are described herein. An LED device includes a light extraction surface, a semiconductor light emitting portion that emits light rays towards the light extraction surface, and at least one bi-convex lens that directs the light rays emitted from the semiconductor light emitting portion such that the light rays exit the light extraction surface in a general direction. The bi-convex lens has a thicker center portion and thinner edge portions surrounding the thicker center portion. The thicker center portion is nearer to the semiconductor light emitting portion than the thinner edge portions.

### CROSS-REFERENCE TO RELATED APPLICATIONS

This application claims the benefit of U.S. Provisional Application No. 63/758,780, filed Feb. 14, 2025, the contents of which are incorporated herein by reference.

### BACKGROUND

Micro displays, such as Liquid Crystal on Silicon (LCoS) displays and Digital Micromirror Devices (DMDs), are increasingly used in applications where compact size and high image quality are important, such as mobile and/or wearable augmented reality (AR) and virtual reality (VR) devices. LCOS displays generally include a liquid crystal layer disposed over a silicon (e.g., CMOS) backplane having reflective pixel electrodes, and incident light from an external illumination source is modulated by the orientation of the liquid crystals in response to electrical drive signals. This technology can provide high resolution and excellent color reproduction, making it suitable for applications requiring detailed images. DMD technology uses an array of tiltable micromirrors, typically fabricated over a silicon (e.g., CMOS) addressing circuit, to selectively reflect incident light from an illumination source and thereby form images by controlling the mirrors with electronic signals. DMD-based displays can provide high brightness and contrast, making them suitable for dynamic content.

### SUMMARY

LED devices are described herein. An LED device includes a light extraction surface, a semiconductor light emitting portion that emits light rays towards the light extraction surface, and at least one bi-convex lens that directs the light rays emitted from the semiconductor light emitting portion such that the light rays exit the light extraction surface in a general direction. The bi-convex lens has a thicker center portion and thinner edge portions surrounding the thicker center portion. The thicker center portion is nearer to the semiconductor light emitting portion than the thinner edge portions.

### BRIEF DESCRIPTION OF THE DRAWINGS

A more detailed understanding can be had from the following description, given by way of example in conjunction with the accompanying drawings wherein:

FIG. 1A is cross-sectional view of an example array of voids;

FIG. 1B is a top view of the example array of microstructures illustrated in FIG. 1A;

FIG. 1C is a perspective view of a single microstructure and represents one of the voids/cavities in the array of FIGS. 1A and 1B;

FIG. 1D is a side view of the microstructure of FIG. 1C showing the curvature of the cross-sectional shape of the microstructure;

FIG. 2A is cross-sectional view of an example array of bi-convex microstructures taken along the line B-B in FIG. 2B;

FIG. 2B is a top view of the example array of bi-convex microstructures illustrated in FIG. 2A;

FIG. 2C is a side view of a single bi-convex microstructure and represents one of the void-lens pairs in the array of FIGS. 2A and 2B;

FIG. 2D is a perspective view of a portion of an array of the bi-convex microstructures of FIG. 2C;

FIG. 3 is a graph showing a comparison of the beam profile among the flat epitaxial emissive layer, the array of air voids, and the array of bi-convex microstructures;

FIG. 4 is a diagram showing an example truncated tear drop shape;

FIG. 5A is a cross sectional view of an example array of individual lenses, which are disposed on an emission surface of the epitaxial layer;

FIG. 5B is a side view of a single one of the lenses of FIG. 5A showing the curvature of the cross-sectional shape of the lens;

FIG. 6A is a cross sectional view of another example array of individual lenses, which are disposed on an emission surface of the epitaxial layer;

FIG. 6B is a side view of a single one of the lenses of FIG. 6A showing the curvature of the cross-sectional shape of the lens; and

FIG. 7 is a flow diagram of an example method of manufacturing a bi-convex microstructure array, such as illustrated in FIGS. 2A-2D.

### DETAILED DESCRIPTION

Examples of different light illumination devices or systems will be described more fully hereinafter with reference to the accompanying drawings. These examples are not mutually exclusive, and features found in one example may be combined with features found in one or more other examples to achieve additional implementations. Accordingly, it will be understood that the examples shown in the accompanying drawings are provided for illustrative purposes only and they are not intended to limit the disclosure in any way. Like numbers refer to like elements throughout.

It will be understood that, although the terms first, second, third, etc. may be used herein to describe various elements, these elements should not be limited by these terms. These terms may be used to distinguish one element from another. For example, a first element may be termed a second element and a second element may be termed a first element without departing from the scope of the present invention. As used herein, the term “and/or” may include any and all combinations of one or more of the associated listed items.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there may be no intervening elements present. It will also be understood that when an element is referred to as being “connected” or “coupled” to another element, it may be directly connected or coupled to the other element and/or connected or coupled to the other element via one or more intervening elements. In contrast, when an element is referred to as being “directly connected” or “directly coupled” to another element, there are no intervening elements present between the element and the other element. It will be understood that these terms are intended to encompass different orientations of the element in addition to any orientation depicted in the figures.

Relative terms such as “below,” “above,” “upper,”, “lower,” “horizontal” or “vertical” may be used herein to describe a relationship of one element, layer, or region to another element, layer, or region as illustrated in the figures. It will be understood that these terms are intended to encompass different orientations of the device in addition to the orientation depicted in the figures.

Designing optical systems for mobile devices, such as watches and AR/VR glasses, is extremely challenging for a number of reasons. First, mobile devices are comparatively small, which strongly limits the amount of space available for the light source engine, not only in the X and Y directions (or width and length dimensions) but also in the Z direction (or depth dimension). This makes it exceptionally difficult to impossible to place optical elements that are conventionally used in lighting applications, such as collimators, micro-lens arrays, individual lenses, and masks (for avoiding stray light), between the bare light source and the image formation object (e.g., LCOS, filter, DMD, etc.). Second, high contrast, resolution and optical efficacy are required, especially for AR/VR applications. With the limited amount of space available for the optics that would conventionally be used to achieve high contrast, resolution and optical efficacy, unconventional optical elements or designs are needed in order to achieve high contrast, resolution and optical efficacy. In embodiments described herein, the typical Lambertian beam profile emitted by a bare emitter/pixel may be altered to better fit the small aperture of mobile optical systems. This is conventionally done by shaping the beam pattern of emitters/pixels in mobile applications over a narrow emission cone, which is typically in the range of ±30 degrees or less. This approach may enable reduction in the number of additional optical elements located between emitters/pixels and associated formation elements of mobile devices, resulting in reduction of the size of the backlight assembly.

One conventional mechanism for shaping the beam pattern of emitters/pixels is the use of patterned epitaxial layers. The epitaxial emissive layers may be patterned to form microstructures therein. The microstructures may be voids or cavities, which may be at maximum a few micrometers in size. The patterning may remove material from the otherwise flat epitaxial outer surface to form an array of voids.

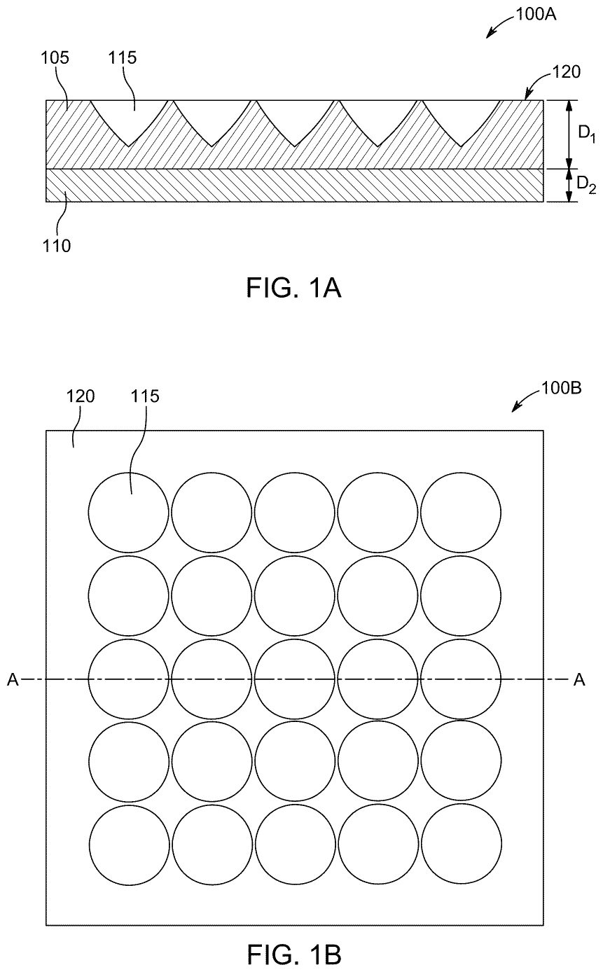

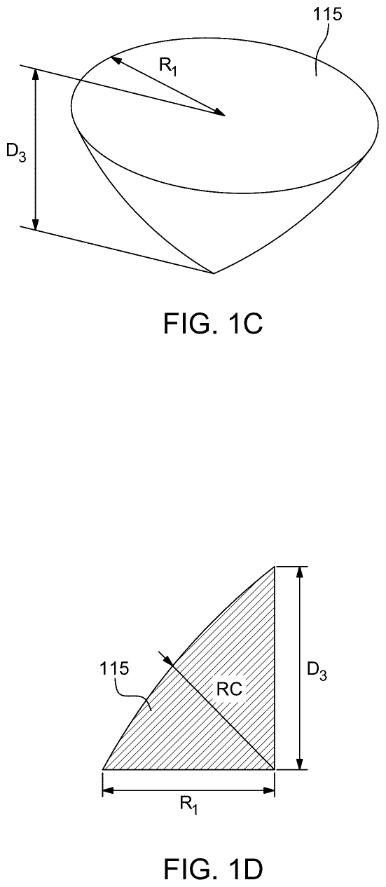

FIG. 1A is a cross-sectional view 100A of an example array of microstructures 115 taken along the line A-A in FIG. 1B. FIG. 1B is a top view 100B of the example array of microstructures 115 illustrated in FIG. 1A. In both FIGS. 1A and 1B, the array of microstructures may be formed in a top surface 120 of the epitaxial layers 105. Each of the microstructures 115 may be aligned with a respective one of the emitters/pixels, which are spaced apart from one another at a comparatively small pitch between adjacent emitters/pixels.

In the example illustrated in FIG. 1A, the epitaxial layers 105 may be formed from Gallium Nitride (GaN) and may be formed over one or more layers of metal material 110. While the individual epitaxial sublayers are not shown in FIGS. 1A and 1B, a person of ordinary skill in the art will understand that an epitaxial stack generally includes at least an n-type layer, an active (light-emitting) layer/region, and a p-type layer grown in sequence to form a p-n junction. The one or more metal layers 110 may include a reflective structure, such as a multilayer mirror, disposed on an opposite side of the epitaxial layers 105 from the microstructures 115, and configured to reflect light toward the microstructures 115 and an output side of the device. In an LCOS implementation, the structure of FIG. 1A may be used as an illumination source that provides light to an LCOS modulator disposed along the output light path, the LCOS modulator including a CMOS backplane having a reflective pixel electrode/mirror structure and a liquid-crystal layer disposed over the reflective pixel structure. The LCOS modulator may thereby modulate the incident light on a pixel-by-pixel basis to generate a display output. The emitters/pixels described above, therefore, may correspond to pixels in a display structure, in an LCOS (or DMD in another example).

While GaN is used for the epitaxial layers in the illustrated examples, one of ordinary skill in the art will recognize that other semiconductor materials may be used to form the epitaxial layers, consistent with the embodiments described herein. Additionally, in the illustrated example, the one or more metal layers 110 are formed from silver (Ag). However, the one or more metal layers 110 may be, for example, any material that is usable to electrically contact the epitaxial layer, to dissipate heat, and/or to provide reflectivity to direct light emitted by the epitaxial layers. In some embodiments, as mentioned above, the one or more metal layers 110 may be a multi-layer mirror. In the illustrated example, the epitaxial layers 105 have a height D₁, and the one or more metal layers 110 have a height D₂. As shown in both the cross-sectional and top views in FIG. 1A and FIG. 1B, the epitaxial layers 105 have been patterned to form an array of microstructures 115, which may be voids and/or cavities (“voids/cavities”). In the example illustrated in FIG. 1A and FIG. 1B, the array is a 5×5 array of voids/cavities, although an array of any number of voids/cavities may be formed depending on the spacing between emitters/pixels and the size of the display.

FIG. 1C is a perspective view 100C of a single microstructure 115 and represents one of the voids/cavities 115 in the array of FIGS. 1A and 1B. FIG. 1D is a side view 100D of the microstructure 115 of FIG. 1C showing the curvature of the side surfaces of the cross-sectional shape of the void/cavity. In the examples illustrated in FIGS. 1C and 1D, the microstructure 115 has a conical shape with a depth D₃, a radius R₁, and a radius of curvature RC. In the illustrated embodiment, the depth D₃ is approximately 1.4 μm, the radius R₁ of the cone is fixed to approximately 1.2 μm, and the radius of curvature (RC) is approximately 1 μm. While the best results may considered to be attainable using a hexagonal lattice arrangement, a regular array with a pitch of 2.5 μm between adjacent microstructures is used in the illustrated example for simplicity. One of ordinary skill in the art will, however, recognize that a hexagonal lattice arrangement could be used consistent with the embodiments described herein. The radius R₁ may be chosen based at least in part on the pitch between adjacent emitters/pixels in the lighting device such that, in the illustrated embodiment, adjacent microstructures do not touch, and other dimensions, including D₃ and RC can be adjusted accordingly.

The cavities may be filled with air or with any material having a refractive index (RI) of approximately 1.0 (approximately the RI of air). The extraction efficiency at the interface between the epitaxial layer and air may be optimized within the range of ±30 degrees (an approximately 60 degree spread) when the voids are filled with air.

Ray tracing software has been used to compute the optical power gain, relative to the flat top surface of the epitaxial layer, of the example 5×5 array of voids/cavities illustrated in FIGS. 1A-D, with the voids filled with air. For this computation, a test structure has been created by embedding a 1-watt light-emitting sheet in a 2 μm thick GaN epitaxial layer and depositing the resulting structure on an Ag mirror structure. The 5×5 array was chosen as it is assumed to be enough to minimize edge effect during the simulation. The results of the simulation are provided in TABLE 1 below, which provides the optical power gain of the test structure relative to a flat epitaxial emissive layer.

TABLE 1

| | P_{optical} Gain Relative | P_{optical} Gain Relative |
|---|---|---|
| | to Flat Epitaxial | to Flat Epitaxial |
| | Emissive Layer Over 2π | Emissive Layer Over ±30° |
| | Collection Angle | Collection Angle |
| 5 × 5 Array of | +62% | +112% |
| Microstructures | | |

As shown in TABLE 1 above, the test structure provides a gain of 62% relative to the bare flat epitaxial emissive layer (for a 2π collection angle) and a gain of 11% relative to the bare flat epitaxial emissive layer (for ±30 degrees collection angle). While this gain is not insignificant, further optical analyses show that the structure illustrated in FIGS. 1A-D is not optimal and that higher optical power gain can be achieved with a different microstructure design.

In embodiments described herein, therefore, the top of the epitaxial layer may be patterned with bi-convex microstructures having defined shapes, which may be filled with a low RI material, to maximize optical power within a narrow collection angle. The voids may be aligned with convex lens structures (or protrusions) having defined shapes, as described in detail hereinbelow, which may be filled with a high RI material. Using such structures, light extraction within a ±30° collection angle may be improved, and higher optical power gain may be achieved. Methods of manufacturing such an optimized bi-lens design are also described herein. The low RI cavity effectively refracts radiation upward, producing the desired angular radiation profile. The RI may be optimized along with the surface curvatures, examples of which are provided for the examples provided below.

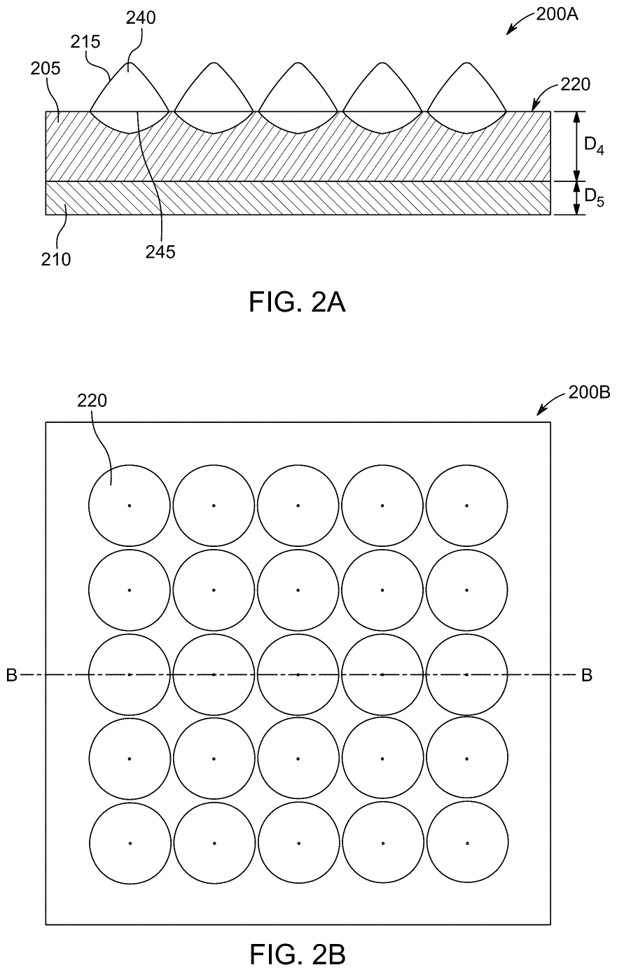

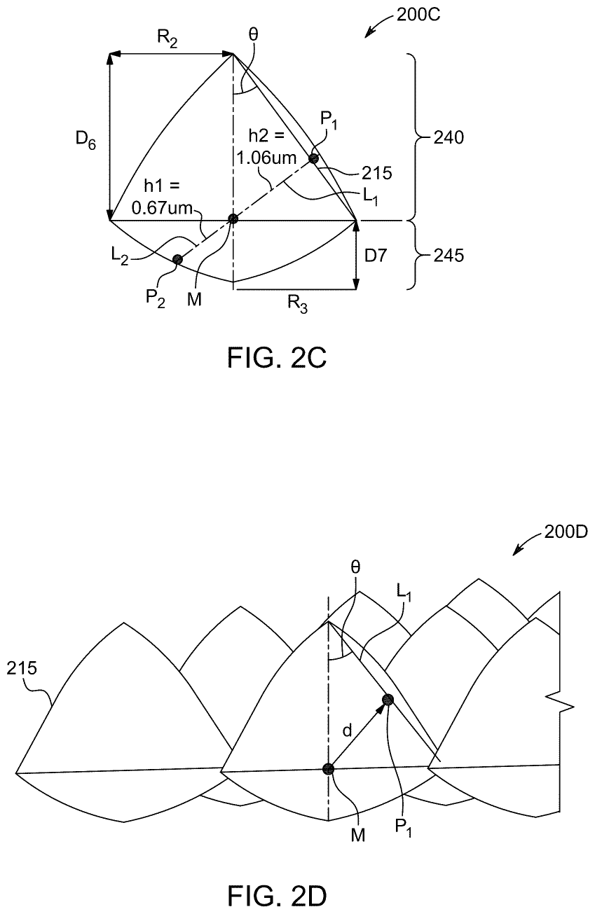

FIG. 2A is a cross-sectional view 200A of an example array of bi-convex microstructures 215 taken along the line B-B in FIG. 2B. FIG. 2B is a top view 200B of an example array of bi-convex microstructures 215. The array of bi-convex microstructures 215 may include voids/cavities 245 formed in the top surface 220 of the epitaxial layers 205 of a semiconductor wafer, and a convex lens structure 240 formed over each of the voids/cavities and the top surface 220 of the epitaxial layers 205 in some cases. This is shown in FIG. 2A with microstructures formed in the top surface 220 of the epitaxial layer 205, forming voids/cavities 245, and the microstructures 240 formed over the voids/cavities 245, forming convex lens structures 240. Each of the bi-convex microstructures 215, comprising a pair of a void/cavity 245 and a convex lens structure 240, may be aligned with a respective one of the emitters/pixels, which are spaced apart from one another at a comparatively small pitch between adjacent emitters/pixels, as described in more detail above with respect to FIGS. 1A-1D.

In the example illustrated in FIG. 2A, as also explained above with respect to FIGS. 1A-1D, the epitaxial layers 205 are formed from Gallium Nitride (GaN) and are formed over one or more layers of metal material 210. While GaN is used for the epitaxial layers 205 in the illustrated examples, one of ordinary skill in the art will recognize that other semiconductor materials may be used to form the epitaxial layers 205, consistent with the embodiments described herein. Additionally, in the illustrated example, the one or more metal layers 210 are formed from silver (Ag). However, the one or more metal layers 210 may be, for example, any metal material that is suitable for electrically contacting the epitaxial layers 205, to dissipate heat, and/or to provide reflectivity to direct light emitted by the epitaxial layers 205. In some embodiments, as explained in more detail below, the one or more metal layers 210 may be a multi-layer mirror. In the illustrated example, the epitaxial layers 205 have a total height D₄, and the one or more metal layers 210 have a total height D₅. The top surface 220 of the epitaxial layers 205 has been patterned to form an array of the voids/cavities 245. In the example illustrated in FIG. 2A and FIG. 2B, a convex lens 240 is provided over each of the voids/cavities 245, creating a 5×5 array of the bi-convex microstructures 215, which are formed from pairs of voids/cavities 245 and convex lenses 240, as described in more detail below. These bi-convex microstructures 215 may also be referred to herein as void-lenses.

FIG. 2C is a side view 200C of a single bi-convex microstructure 215 and represents one of the void-lens pairs in the array of FIGS. 2A and 2B. FIG. 2D is a perspective view 200D of a portion of an array of the bi-convex microstructures 215 of FIG. 2C.

In the examples illustrated in FIGS. 2C and 2D, the bi-convex microstructure 215 has a shape defined by a conical convex lens 240 formed over a conical void/cavity 245. The conical convex lens 240 has a depth D₆ and a radius R₂. The conical void/cavity 245 has a depth D₇ and a radius R₃. In the illustrated embodiment, the depth D₆ is approximately 1.55 μm, and the radius R₂ of the cone is fixed to approximately 1.2 μm for ease of comparison. The depth D₇ is approximately 0.6 μm, and the radius R₃ of the cone is fixed to approximately 1.2 μm. The radii R₂ and R₃ should be similar and may be maximized to obtain the best light extraction and collimation efficacy. The radii R₂ and R₃ may be chosen based at least in part on the pitch between adjacent emitters/pixels in the lighting device such that, in the illustrated embodiment, the radii R₂ and R₃ are maximized while also preventing adjacent bi-convex microstructures from touching. The other dimensions may be determined based on the chosen values for R₂ and R₃, which may vary depending on the pitch between LEDs in the array. The values of R₂ and R₃ may be chosen to match the value of R₁ for ease of comparison.

The conical convex lens 240 may be formed from a material having a high RI, while the conical void/cavity 245 may be filled with a material having a low RI. A material having a low RI may be defined as a material having an RI of approximately 1.6 or lower (with 1.4 being optimal for the example bi-convex microstructure). A material having a high RI may be defined as a material having an RI of approximately 1.8 or higher (with 2.04 being optimal for the example bi-convex microstructure). These ranges were chosen at least in part because materials having these properties will not dramatically reduce optical gain. In some embodiments, the conical convex lenses 240 may be covered with a third material having an RI between the RI of the conical convex lenses 240 and the RI of air.

The shape of the bi-convex microstructures may be defined based on the dimensions h1 and h2. As shown in FIG. 2C, a line L1 may be drawn between the midpoint M of the base of the convex lens 240 and a point P₁ on the outer surface of the convex lens 240 that is at a height

$$\frac{D 6}{2} .$$

The line may be extended through the midpoint M until it reaches the outer surface of the void/cavity 245 at point P₂ that is at height

$$\frac{D 7}{2} .$$

The dimension h1 represents the length of a line L₁ between M and P₁. The dimension h2 represents the length of the line L₂ between M and P2. For comparison, FIG. 2D illustrates the line L₁ drawn at an angle, θ, with respect to the midpoint of one of the conical convex lenses 240. In the illustrated example, θ is 45°. The distance, d, between the midpoint, M, of the conical convex lens 240 and the line L₂ may be calculated such that

$$d = \frac{\sqrt{{width}^{2} + {height}^{2}}}{4} ,$$

where the width may be equal to 2R₂ and the height may be equal to D₆. The optimized shape may, however, not be a perfect cone with straight side surfaces. Rather, for the optimized shape, h₂>d. A similar rule may be defined for the conical void/cavity 245 to ensure that both the conical void/cavity 245 and the conical convex lens 240 have a convex shape.

Parameter sensitivity analysis has been performed on the bi-convex microstructure of FIGS. 2C and 2D and indicates that that the convexity of the conical void/cavity 245 and the conical convex lens 240 should not deviate greatly from the optimized dimensions described herein to maintain optimized optical gain. To the extent a dimension of the emitters/pixels or their pitch is changed from the example dimensions provided herein, the ratios of such dimensions should be kept relatively consistent, for example by scaling of the dimensions based on the changed dimension. For example, if an emitter/pixel array with a different emitter-to-emitter or pixel-to-pixel pitch is used, the other dimensions of the bi-convex microstructure should change by a similar multiplier. Convexity and RI are, therefore, two important parameters to consider when optimizing bi-convex microstructures based on embodiments described herein. For example, a cone with straight side surfaces or side surfaces having a concave shape may not provide the expected optical gain.

The interface between the conical convex lens 240 and the void/cavity 245, which may be defined as the horizontal plane on which the point M resides (and co-planar with the top surface 220 of the epitaxial layer 205), is expected to be flat. It is similarly expected that the conical convex lens 240 is perfectly aligned with the corresponding void/cavity 245 to form a bi-convex microstructure. However, the parameter sensitivity analysis shows that the diameter of each lens can be different and that the interface is not strictly required to be perfectly flat. A certain deviation of up to a few ums may be tolerated. For example, the radius of the conical convex lens 240 may be slightly longer than the radius of the corresponding conical void/cavity 245 resulting in at least a portion of the conical convex lens 240 being disposed on the top surface 220 of the epitaxial layer 205.

Ray tracing software has been used to compute the optical power gain of the example 5×5 array of bi-convex microstructures illustrated in FIGS. 2A-2D relative to the flat top surface 220 of the epitaxial layer 205. For this computation, a test structure has been created by embedding a 1-watt light-emitting sheet in a 2 μm thick GaN epitaxial layer(s) and depositing the resulting structure on an Ag mirror structure. The 5×5 array was chosen as it is assumed to be enough to minimize edge effect during the simulation. The results of the simulation are provided in TABLE 2 below, which provides the optical power gain of the 5×5 array of bi-convex microstructures 215 relative to a flat epitaxial emissive layer as well as the optical power gain of the 5×5 array of microstructures relative to a flat epitaxial emissive layer (e.g., corresponding to FIGS. 1A-1D).

TABLE 2

| | P_{optical} Gain Relative | P_{optical} Gain Relative |
|---|---|---|
| | to Flat Epitaxial | to Flat Epitaxial |
| | Emissive Layer Over 2π | Emissive Layer Over ±30° |
| | Collection Angle | Collection Angle |
| 5 × 5 Array of | +62% | +112% |
| Microstructures | | |
| 5 × 5 Array of | +47% | +147% |
| Bi-convex | | |
| microstructures | | |

As shown in TABLE 2 above, the epitaxial layer comprising the 5×5 array of bi-convex microstructures provides less optical gain relative to a flat epitaxial emissive layer (47% compared with 62%) (for a 2π collection angle), but provides more optical gain relative to the flat epitaxial emissive layer (147% compared with 112%) (for a ±30 degrees collection angle). Since a smaller collection angle is applicable for mobile devices, and especially for AR/VR devices, the 5×5 array of bi-convex microstructures provides significantly more optical gain within the applicable collection angle, making the array of bi-convex microstructures ideal for use in such devices.

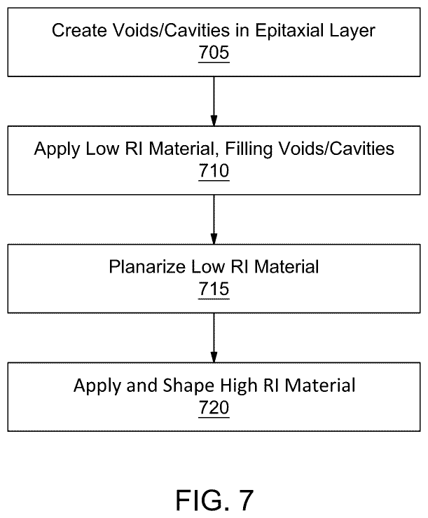

FIG. 7 is a flow diagram of an example method of manufacturing a bi-convex microstructure array, such as illustrated in FIGS. 2A-2D. In an example method, epitaxial layers may be grown on a patterned sapphire substrate (PSS). A thin film process may allow sapphire removal. In the example illustrated in FIG. 7, the method includes creating voids/cavities in the epitaxial layer (705). The voids/cavities may be formed in the epitaxial layer surface (e.g., GaN surface) exposed after the sapphire removal, for example. The voids/cavities may be formed, for example, using etching methods such as, but not limited to, chemical wet etching, dry etching, or sputtering. A layer of low RI material may then be deposited over the full wafer area to cover and thereby fill the voids/cavities with the low RI material (710). The material may be chosen, for example, based on the considerations mentioned above. The layer of the low RI material may be planarized (715) such that only the low RI material filling the voids/cavities remains. A second layer of high RI material may be deposited over the top surface of the epitaxial layers and shaped (720). The high RI material may be chosen and shaped based on the considerations mentioned above. The shape may be formed by depositing and etching the high RI material in one or more steps to form the selected convex lens shape. In some embodiments, once the epitaxial layers are formed and patterned, as described herein, the resulting array of emitters/pixels with embedded bi-convex microstructures may be optically coupled to a light modulation panel, such as an LCOS display or DMD. The thereby formed display may then be inserted or otherwise coupled to a device, such as a mobile, e.g., AR/VR device, as would be recognized by one of ordinary skill in the art.

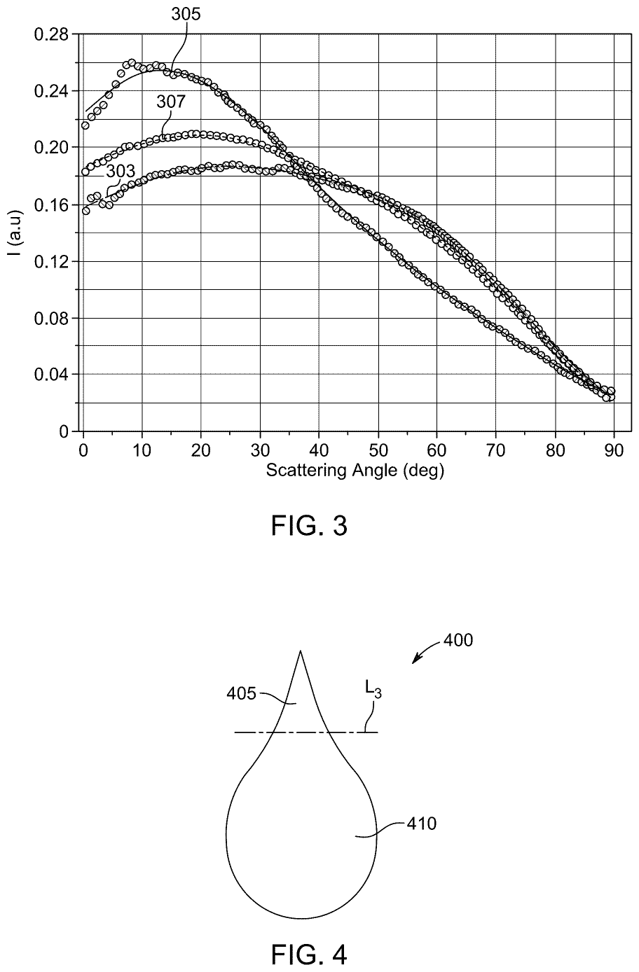

FIG. 3 is a graph showing a comparison of the beam profile among the flat epitaxial emissive layer (307), the array of air voids (303), and the array of bi-convex microstructures (305). As is clearly visible in FIG. 3, the beam profile of the array of bi-convex microstructures (305) is narrower and deviates strongly from the Lambertian emission profile of the flat epitaxial emissive layer (307).

In some embodiments, individual lenses may take the place of the bi-convex microstructures. In such embodiments, the entire lens may be formed from the same optical material. In some embodiments the material used for the lenses may have an RI of approximately 1.6±0.15 so they can be patterned during the same process step. The material may be or include a dielectric, such as, for example, poly(methyl methacrylate) (PMMA), Titanium Dioxide (TiO₂) or Silicone Dioxide (SiO₂). Such individual lenses may have a bi-convex shape, such as described above, or a truncated tear drop shape.

FIG. 4 is a diagram showing an example lens 400 having a truncated tear drop shape, as illustrated. In the example illustrated in FIG. 4, the tear drop shape is truncated at the line L3, forming a flat surface that can be disposed on top of the top surface of the epitaxial layer (e.g., the top surfaces of any of the epitaxial layers illustrated in FIG. 1A, 1B, 2A or 2B (either directly or via an adhesive, such as a thing (few nm atomic layer deposition (ALD) coating, for example).

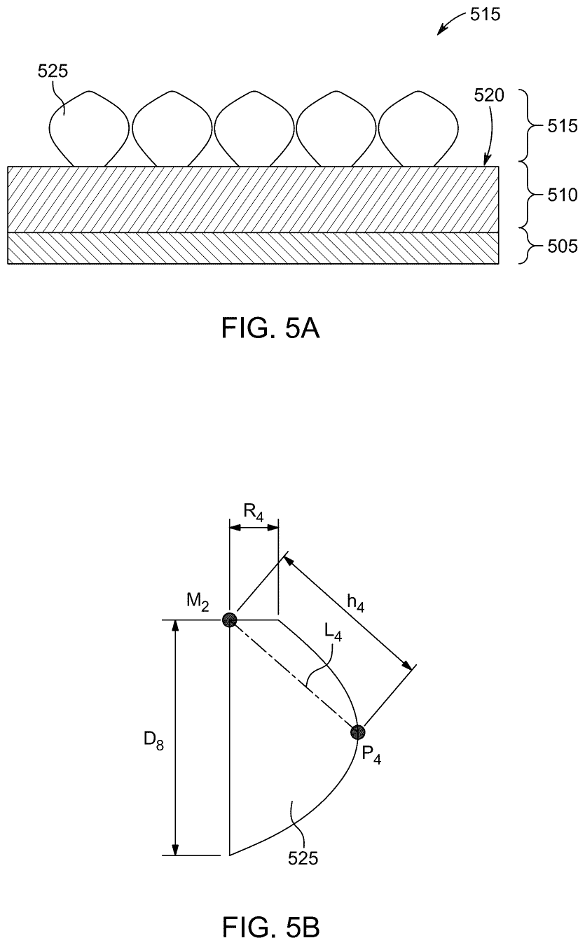

FIG. 5A is a cross sectional view of an example array 515 of individual lenses 525, which are disposed on an emission/top surface 520 of the epitaxial layers 510. The epitaxial layers 510 may be disposed over one or more layers of metal 505, similar to the structures illustrated in FIGS. 1A and 2A. In the example illustrated in FIG. 5A, the individual lenses 525 in the example array 515 touch adjacent lenses. The individual lenses 505 in the example array 515 each have a truncated tear drop shape, similar to the shape of the lens 400 illustrated in FIG. 4.

FIG. 5B is a side view of a single one of the lenses 525 of FIG. 5A showing the curvature of the cross-sectional shape of the lens. Similar to FIGS. 2C and 2D, the shape of the lens 525 may be defined based on the dimension h₄. As shown in FIG. 5B, a line L₄ may be drawn between the midpoint M₂ of truncated base of the lens 525 and a point P₄ on the outer surface of the lens 525 that is at a height

$$\frac{D 8}{2} .$$

The dimension h₄ represents the length of the line L₄. For basis of comparison with the structures illustrated in FIGS. 1C and 2C, it can be considered that the lenses 525 in the lens array 515 are embedded in air (rather than, for example, GaN). In the example illustrated in FIG. 5B, the height, D₈, of the lenses may be approximately 2.3 μm, the radius, R₄, of the truncated base may be approximately 0.48 μm, and h₄ is approximately 1.66 μm.

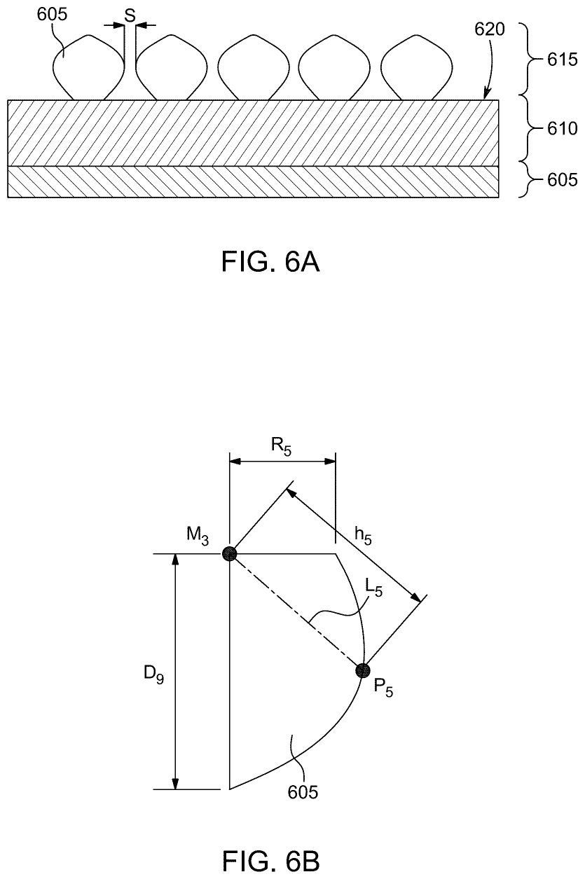

FIG. 6A is a cross sectional view of another example array 615 of individual lenses 605, which are disposed on an emission/top surface 620 of the epitaxial layer 610. The epitaxial layers 610 may be disposed over one or more layers of metal 605, similar to the structures illustrated in FIGS. 1A and 2A. In the example illustrated in FIG. 6A, the individual lenses 605 in the example array 615 are minimally spaced apart at a distance, s, from adjacent lenses at their widest sections. In some embodiments, s may be approximately equal to 0.21 μm based on example dimensions. The individual lenses in the exemplary array 615 each have a truncated tear drop shape, similar to the shape of lens 400 illustrated in FIG. 4.

FIG. 6B is a side view of a single one of the lenses 605 of FIG. 6A showing the curvature of the cross-sectional shape of the lens 605. Compared to the shape of the lenses 505 of FIGS. 5A and 5B, the shape and dimensions of the lenses 605 may differ slightly, for example, to allow for the minimal spacing, s, between the adjacent emitters/pixels. Similar to FIGS. 2C and 2D, the shape of the lens 605 may be defined based on the dimension h₅. As shown in FIG. 6B, a line L₅ may be drawn between the midpoint M₃ of truncated base of the lens and a point P₅ on the outer surface of the lens 605 that is at a height

$$\frac{D 9}{2} .$$

The dimension h₅ represents the length of the line L₅. For basis of comparison with the structures illustrated in FIGS. 1C and 2C, it can be considered that the lenses 605 in the lens array 615 are embedded in air (rather than, for example, GaN).

The lenses would ideally be in contact with each other, as in FIG. 5A, forming a continuous (non-uniform in thickness) layer with RI approximately equal to 1.6±0.15. As shown in TABLE 3 below, such an arrangement provides a maximum optical gain of 244% for a ±30 degrees collection angle. If a gap between adjacent lenses is set to 0.21 μm, as in FIG. 6A, to simplify the deposition process, optical gain relative to the flat epitaxial emission surface drops to 189%, as also shown in TABLE 3.

TABLE 3

| | P_{optical} Gain Relative | P_{optical} Gain Relative |
|---|---|---|
| | to Flat Epitaxial | to Flat Epitaxial |
| | Emissive Layer Over 2π | Emissive Layer Over ±30° |
| | Collection Angle | Collection Angle |
| 5 × 5 Array of | +62% | +112% |
| Microstructures | | |
| 5 × 5 Array of | +47% | +147% |
| Bi-Convex | | |
| Microstructures | | |
| Single Lens | +63% | +244% |
| Having Truncated | | |
| Drop Shape | | |
| Without Spacing | | |
| Between Lenses | | |
| Single Lens | +65% | +189% |
| Having Truncated | | |
| Drop Shape With | | |
| Spacing Between | | |
| Lenses | | |

Having described the embodiments in detail, those skilled in the art will appreciate that, given the present description, modifications may be made to the embodiments described herein without departing from the spirit of the inventive concept. Therefore, it is not intended that the scope of the invention be limited to the specific embodiments illustrated and described.

What is claimed is:

1. A light emitting diode (LED) device comprising:
a light extraction surface;
a semiconductor light emitting portion configured to emit light rays towards the light extraction surface; and
at least one bi-convex lens configured to direct the light rays emitted from the semiconductor light emitting portion such that the light rays exit the light extraction surface in a general direction, wherein the bi-convex lens comprises:
a thicker center portion, and
thinner edge portions surrounding the thicker center portion,
wherein the thicker center portion is nearer to the semiconductor light emitting portion than the thinner edge portions.

2. The device of claim 1, wherein:
the device further comprises epitaxial layers that comprise the semiconductor light-emitting portion, and
the at least one bi-convex lens comprises:
a cavity formed in the epitaxial layers and filled with a first optical material, and
a convex lens formed from a second optical material and disposed over the cavity, wherein the first optical material has a lower refractive index (RI) than the second optical material.

3. The device of claim 2, wherein the RI of the first material is approximately 1.6 or lower, and the RI of the second material is approximately 1.8 or higher.

4. The device of claim 3, wherein the RI of the first material is 1.4, and the RI of the second material is 2.04.

5. The device of claim 2, wherein the cavity has a first conical shape with a first convex side surface, and wherein the convex lens has a second conical shape with a second convex side surface, wherein the first and second conical shapes are different.

6. The device of claim 5, wherein a first base of the first conical shape has a first radius, a second base of the second conical shape has a second radius, and the first and second radii are approximately equal.

7. The device of claim 5, wherein the first conical shape has a first height, the second conical shape has a second height, and the first height is greater than the second height.

8. The device of claim 7, wherein a length of a line between a point on the first convex side surface at a height equal to half the first height, and a midpoint of the first base, is approximately 1.06 μm.

9. The device of claim 7, wherein a length of a line between a point on the second convex side surface at a height equal to half the second height, and a midpoint of the second base, is approximately 0.57 μm.

10. The device of claim 1, wherein:
the device further comprises epitaxial layers that comprise the semiconductor light-emitting portion,
the epitaxial layers comprise a planar top surface, and
the at least one bi-convex lens is formed on the planar top surface and is formed from a dielectric material.

11. The device of claim 10, wherein the bi-convex lens has a tear drop shape having a convex side surface.

12. The device of claim 10, wherein the bi-convex lens has one flat side that forms a base of the bi-convex lens, and the flat side of the bi-convex lens is disposed on the planar top surface of the epitaxial layers.

13. The device of any of claim 11, wherein the at least one bi-convex lens comprises a plurality of tear drop shaped bi-convex lenses.

14. The device of claim 13, wherein the convex side surface of each of the plurality of tear drop shaped bi-convex lenses touches the convex side surface of at least one adjacent one of the plurality of tear shaped bi-convex lenses.

15. The device of claim 14, wherein each bi-convex lens has a height, and a length of a line between a point on the convex side surface at a height equal to half the height of the bi-convex lens, and a midpoint of the base, is approximately 1.66 μm.

16. The lighting device of claim 13, wherein the convex side surfaces of adjacent ones of the plurality of bi-convex lenses do not touch.

17. The lighting device of claim 16, wherein each of the plurality of bi-convex lenses has a height, and a length of a line between a point on the convex side surface at a height equal to half the height of the bi-convex lens, and a midpoint of the base, is approximately 1.50 μm.

18. The device claim 2, wherein:
the epitaxial layers comprise a bottom surface, and
the device further comprises a multi-layer mirror adjacent the bottom surface of the epitaxial layers,
the semiconductor light-emitting portion comprises a plurality of emitters, and
the at least one bi-convex lens comprises a plurality of bi-convex lenses, each adjacent one of the plurality of emitters.

19. A micro-display comprising the device of claim 18, wherein each of the plurality of emitters corresponds to a respective pixel in the micro display.

20. An automotive lighting system comprising the micro-display of claim 19.
